(19) United States
(12) Patent Application Publication
(10) Pub. No.: US 2008/0242073 A1
(43) Pub. Date: Oct. 2, 2008

(54) METHOD FOR FABRICATING A NONVOLATILE MEMORY DEVICE

(75) Inventor: Dong-Gyun Hong, Ochon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyougki-do (KR)

(21) Appl. No.: 11/856,690

(22) Filed: Sep. 17, 2007

(30) Foreign Application Priority Data
Mar. 31, 2007 (KR) 10-2007-0032075

(51) Int. Cl. H01L 21/3205

(52) U.S. Cl. 438/593; 257/E21.294

(57) ABSTRACT

A method for fabricating a nonvolatile memory device includes forming a gate insulation layer and a gate conductive layer for forming a floating gate over a substrate. A portion of the gate conductive layer, the gate insulation layer, and the substrate is etched to form a trench. An isolation structure is formed by filling in the trench. The isolation structure is recessed to a certain depth in the trench. A buffer layer is formed over the substrate structure. Spacers are formed over sidewalls of the buffer layer corresponding to inner sidewalls of the trench. A portion of the recessed isolation structure is etched to form a depression in the isolation structure using the spacers. The spacers are removed followed by removal of the buffer layer. A dielectric layer is formed over the substrate structure, and a control gate is formed over the dielectric layer.

### CROSS-REFERENCE TO RELATED APPLICATIONS

The present invention claims priority to Korean patent application number 10-2007-0032075, filed on Mar. 31, 2007, which is incorporated by reference in its entirety.

### BACKGROUND OF THE INVENTION

The present invention relates to a method for fabricating a semiconductor device, and more particularly, to a method for fabricating a nonvolatile memory device. In more detail, the present invention relates to a nonvolatile memory device in which a plurality of memory cells coupled in series is configured as a unit string and to a method for fabricating the same.

A NAND type flash memory device has been one of the widely used nonvolatile memory devices in which a plurality of memory cells coupled in series is configured as a unit string. The NAND type flash memory device is formed for large scale integration. NAND type flash memory devices have enlarged the application fields for memory devices, which can replace memory sticks, universal serial bus (USB) drivers, and hard disks.

A typical NAND type flash memory device comprises a plurality of memory cells for storing data, e.g., 16, 32, or 64 memory cells, a drain selection transistor for coupling a drain of the first memory cell to a bit line, and a source selection transistor for coupling a source of the last memory cell to a common source line, which is connected in series to configure a string.

FIG. 1 illustrates an equivalent circuit diagram showing a memory cell array of a typical NAND type flash memory device. In this drawing, a string structure configured with 32 memory cells is illustrated as an example.

A typical NAND type flash memory device includes a plurality of memory blocks. A plurality of strings (ST) is arranged in each memory block. Each string includes a drain selection transistor, a source selection transistor, and a plurality of memory cells connected in series between the drain selection transistor and the source selection transistor. A source of the source selection transistor in each string is coupled to a common source line. A gate in each of the drain selection transistors in the strings is coupled to a drain selection line (DSL). A gate of the source selection transistor is coupled to a source selection line (SSL). Each control gate in the memory cells is coupled to individual word lines (WL0 to WL31). BL0 to BLn refer to individual bit lines.

The NAND type flash memory device is vulnerable to interference between adjacent peripheral cells because a unit string is configured with a plurality of memory cells that are coupled in series. To secure reliable device operation and improve yield, it is important to uniformly maintain a threshold voltage, which is a state of the cells configuring the unit string.

An interference effect refers to an event where a threshold voltage of a selected cell changes due to an operation of a peripheral cell adjacent to the selected cell. Such an event may occur in a programming operation for storing data. When performing a programming operation to a second cell adjacent to a first cell that is selected to be read, a capacitance between the first and second cells changes due to electrons supplied into a floating gate of the second cell. Changing capacitance causes an event where a voltage higher than a threshold voltage of the first cell is read when reading the first cell. Such an event results from what is referred to as an interference effect. The amount of electric charges supplied to a floating gate of the selected cell does not change, but the threshold voltage of the selected cell is distorted by the changing state of the adjacent cell in such an event.

The interference effect is an important factor when determining device characteristics of a multiple level cell, which has become more popular recently than a single level cell. Securing an effective field oxide height (EFH) is particularly important as is improving programming speed and reducing the interference effect through an advanced self-aligned-shallow trench isolation (ASA-STI) process. The ASA-STI process is a fabrication process for forming an isolation structure on a scale of 60 nm or smaller for large scale integration. The isolation structure refers to a structure defining an active region. The EFH refers to a distance from a surface of an active region between adjacent floating gates to a dielectric layer. Due to device characteristics, securing the EFH has a trade-off relationship with improved programming speed and a reduction in the interference effect. In other words, as the EFH increases, the programming speed decreases, but the interference effect improves. When the EFH is high, the distance between a contact surface of the dielectric layer and the floating gate decreases. Thus, a coupling effect decreases thereby causing the programming speed to decrease.

Accordingly, in the fabrication process of the NAND type flash memory device using the ASA-STI process, a technology referred to as a wing spacer is introduced to improve the interference effect. This technology includes shielding a space between adjacent floating gates with a control gate.

FIGS. 2A to 2E illustrate cross-sectional views of a typical method for fabricating a NAND type flash memory device using the wing spacer technology.

Referring to FIG. 2A, an oxide-based material forms an isolation structure in a trench. An etch process for controlling an EFH of a cell region is performed to recess the oxide-based material to a certain depth. Thus, an oxide-based layer 103 is formed. Reference numerals 100, 101, and 102 refer to a substrate 100, a tunnel oxide layer 101, and a polysilicon layer 102 for forming a floating gate, respectively.

Referring to FIG. 2B, a wing spacer oxide-based layer 104 is formed over the surface profile of the resultant structure.

Referring to FIG. 2C, an anisotropic etch process, e.g., an etch-back process, is performed to etch the wing spacer oxide-based layer 104. As a result of the etch, wing spacers 104A are formed on sidewalls of the polysilicon layer 102. A portion of the oxide-based layer 103 including substantially the same material as the wing spacers 104A is etched and self-aligned by the wing spacers 104A to form a depression to a certain depth. Reference numeral 103A refers to an etched oxide-based layer 103A.

Referring to FIG. 2D, the wing spacers 104A (FIG. 2C) are removed. Reference numeral 103B represents a further etched oxide-based layer 103B. Referring to FIG. 2E, a dielectric layer 105 is formed over the surface profile of the resultant structure. FIG. 3 illustrates a micrographic image showing a cross-sectional view of a cell structure formed by the aforementioned method. A first spacing distance ‘(1)’ represents an EFH that affects the interference effect. A second spacing distance ‘(2)’ represents an EFH that affects repetitive cycling, i.e., programming and erasing operations. A third spacing distance ‘(3)’ represents an EFH that affects a coupling effect that relates to the processing speed.

The method for fabricating the NAND type flash memory device using the wing spacer technology may secure certain distances for EFHs ‘(1)’ and ‘(2),’ which affect the interference effect and changes in the threshold voltage due to the repetitive cycling between adjacent floating gates. However, the method has difficulty controlling the EFH, ‘(3),’ that affects the coupling effect. The EFH as represented with the third spacing distance ‘(3)’ refers to a distance from a contact point, or surface, between the floating gate and the dielectric layer to an upper surface of an active region. The contact point refers to an end where the floating gate and the dielectric layer are in contact.

The EFH as represented with the third spacing distance ‘(3)’ is often largely affected by a thickness of the wing spacer oxide-based layer 104 and the subsequent removal processes as described in FIGS. 2B to 2D. This result is obtained because the wing spacer material includes an oxide-based material which is substantially the same as the isolation structure material. In other words, the wing spacer oxide-based layer 104 generally needs to be formed to a sufficiently large thickness, as shown in FIG. 2B, to secure the EFH as represented with the second spacing distance ‘(2)’ in FIG. 3. In this case, the etch depth in the oxide-based layer 103A, which forms the isolation structure below the wing spacers 104A, increases due to an increased exposure time during the removal process of the wing spacers 104A as shown in FIG. 2D.

When the etched oxide-based layer 103A is damaged during the removal process of the wing spacers 104A, the EFH determined in FIG. 2A changes as much as the increased etch depth. Also, the EFH changes unevenly in the cell region according to particular process conditions being used. As a result, an evenly distributed threshold voltage may not be obtained. The distribution of the cell programming threshold voltage caused by the interference effect may be improved. However, the distribution of the cell programming threshold voltage by the physical EFH may not be stably obtained through the typical method described above.

### SUMMARY OF THE INVENTION

Embodiments of the present invention describe a method of fabrication using a wing spacer technology to fabricate an improved nonvolatile memory device with reduced interference effects. In particular, the embodiments provide a method for fabricating a nonvolatile memory device which can secure a stable distribution of cell programming threshold voltages by a physical effective field oxide height (EFH).

In accordance with an aspect of the present invention, a method for fabricating a nonvolatile memory device includes forming a gate insulation layer and a gate conductive layer for forming a floating gate over a substrate. A portion of the gate conductive layer, the gate insulation layer, and the substrate is etched to form a trench. An isolation structure is then formed by filling in the trench. The isolation structure is recessed to a certain depth in the trench. A buffer layer is formed over a resulting surface profile of the substrate structure. Spacers, which include a material having a high etch selectivity relative to the buffer layer, are formed over sidewalls of the buffer layer corresponding to inner sidewalls of the trench. A portion of the recessed isolation structure is etched to form a depression in the isolation structure using the spacers. The spacers are removed followed by removal of the buffer layer. A dielectric layer is formed over the surface profile of the substrate structure. A control gate is formed over the dielectric layer.

Another aspect of the present invention relates to a method for fabricating a nonvolatile memory device that includes a cell region and a peripheral region. The method includes forming a gate insulation layer and a gate conductive layer to form a floating gate over a cell region and a peripheral region of a substrate. A portion of the gate conductive layer, the gate insulation layer, and the substrate is etched to form a trench. An isolation structure is formed by filling in the trench. A portion of the isolation structure is recessed in the cell region to a certain depth in the trench. A buffer layer is formed over a resultant surface profile of the substrate structure. Spacers, which include a material having a high etch selectivity relative to the buffer layer, are formed over sidewalls of the buffer layer corresponding to inner sidewalls of the trench. A portion of the recessed isolation structure is etched to form a depression in the isolation structure using the spacers. The spacers are removed followed by removal of the buffer layer. A dielectric layer is formed over the surface profile of the substrate structure. A control gate is formed over the dielectric layer.

### BRIEF DESCRIPTION OF THE DRAWINGS

FIG. 1 illustrates an equivalent circuit diagram showing a memory cell array of a typical NAND type flash memory device.

FIGS. 2A to 2E illustrate cross-sectional views of a typical method for fabricating a NAND type flash memory device using a wing spacer technology.

FIG. 3 illustrates a micrographic image showing a cross-sectional view of a cell fabricated using a typical wing spacer technology.

FIGS. 4A to 4F illustrate cross-sectional views of a method for fabricating a nonvolatile memory device in accordance with an embodiment of the present invention.

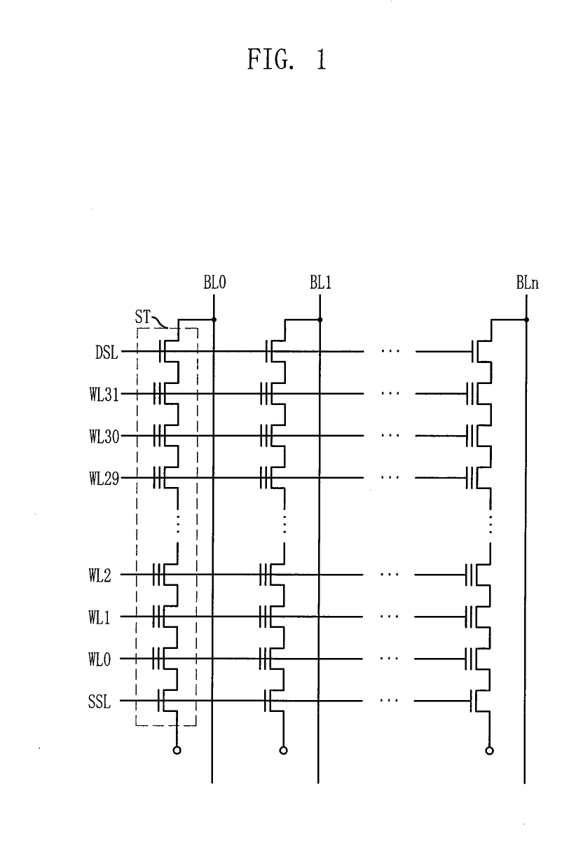

### DESCRIPTION OF SPECIFIC EMBODIMENTS

Embodiments of the present invention relate to a method for fabricating a nonvolatile memory device.

Referring to the drawings, the illustrated thickness of layers and regions are exaggerated to facilitate explanation. When a first layer is referred to as being “on” a second layer or “on” a substrate, “on” could mean that the first layer is formed directly on the second layer or the substrate. Or, “on” could also mean that a third layer may exist between the first layer and the substrate. Furthermore, the same or similar reference numerals, e.g., 103 and 103B, throughout the various embodiments of the present invention represent the same or similar elements in different drawings. Reference numerals including English capital letters represent elements changed in form by an etch process.

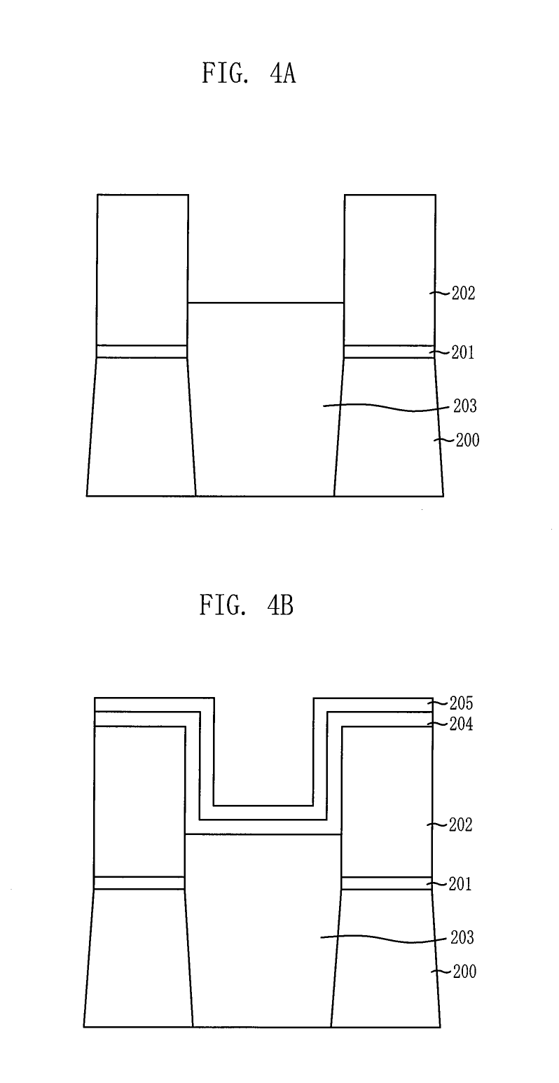

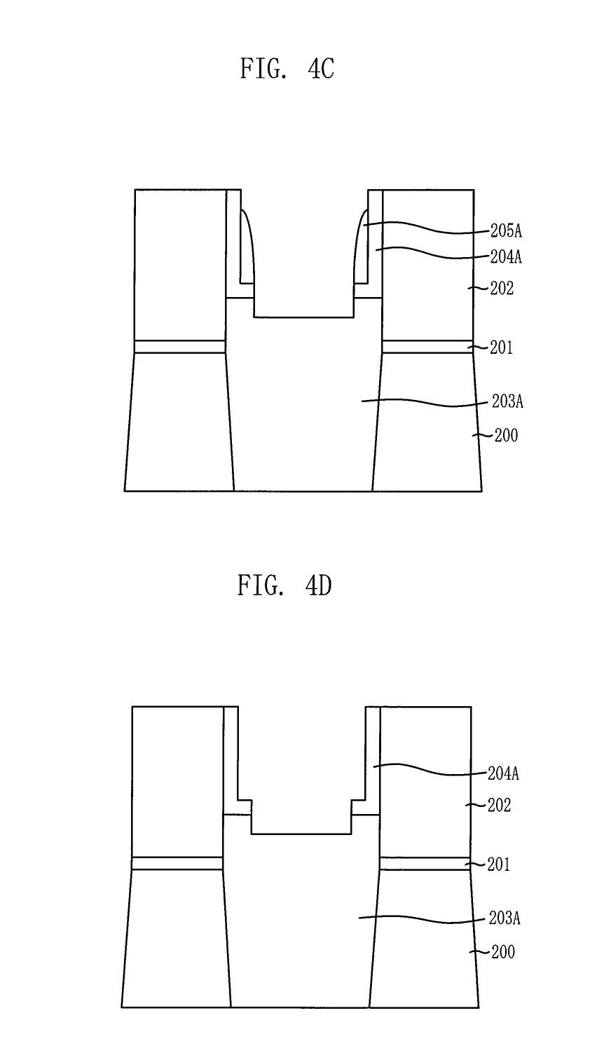

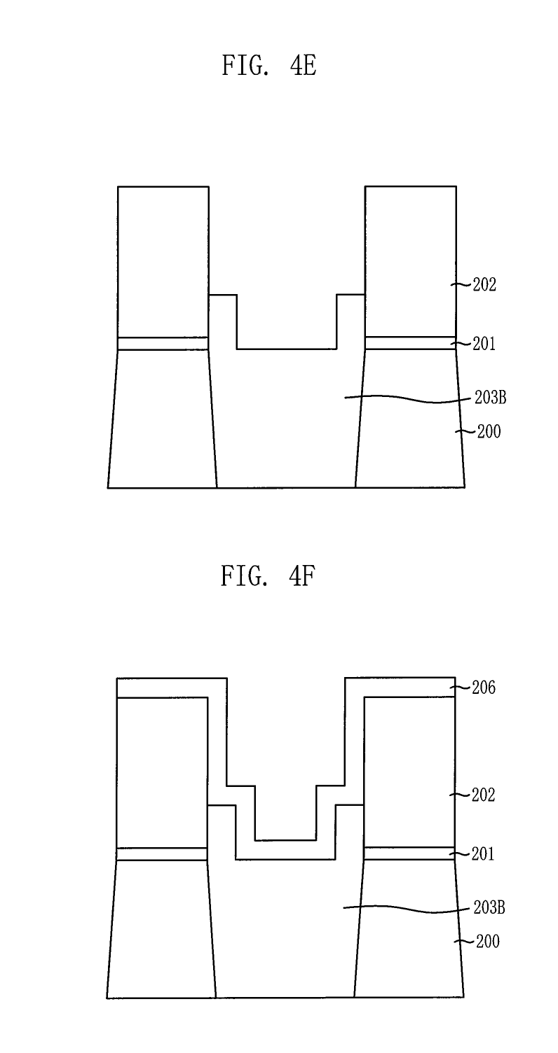

FIGS. 4A to 4F illustrate cross-sectional views of a method for fabricating a nonvolatile memory device in accordance with an embodiment of the present invention.

Referring to FIG. 4A, a patterned gate insulation layer 201 and a patterned conductive layer 202 are formed over a P-type substrate 200. Reference numeral 203 refers to a recessed first insulation layer 203.

In more detail, although not illustrated, a triple N-type well is formed in the substrate 200. A P-type well is formed in the resultant structure. An ion implantation process is performed to provide a specified threshold voltage. A gate insulation layer, in which actual P-N tunneling occurs, is formed over the substrate 200. The gate insulation layer includes an oxide-based layer, e.g., silicon oxide (SiO₂) or a stack structure configured with an oxide-based layer and nitride-based layer. The fabrication method of the gate insulation layer includes a dry oxidation process, a wet oxidation process, or a radical oxidation process.

A conductive layer functioning as a floating gate is formed over the gate insulation layer. The conductive layer includes a material having conductivity. For instance, the conductive layer may include polysilicon, transition metals, or rare earth metals.

For example, the polysilicon may include an undoped polysilicon layer, which is not doped with impurities, or a doped polysilicon layer, which is doped with impurities. The undoped polysilicon layer is implanted with impurities through a subsequent ion implantation process. Such polysilicon is formed by performing a low pressure chemical vapor deposition (LPCVD) method using a source gas of silane (SiH₄) and a doping gas of phosphine (PH₃), trichloroborane (BCl₃), or diborane (B₂H₆) gas. The transition metals may include iron (Fe), cobalt (Co), tungsten (W), nickel (Ni), palladium (Pd), platinum (Pt), molybdenum (Mo), or titanium (Ti). The rare earth metals may include erbium (Er), ytterbium (Yb), samarium (Sm), yttrium (Y), lanthanum (La), cerium (Ce), terbium (Tb), dysprosium (Dy), holmium (Ho), thulium (Tm), or lutetium (Lu).

A buffer layer (not shown) and a padding layer (not shown) are formed over the conductive layer. The buffer layer includes an oxide-based layer, and the padding layer includes a nitride-based layer. Hereinafter, the buffer layer and the padding layer are referred to as the buffer oxide layer and the pad nitride layer, respectively. An etch process is performed to etch a portion of the pad nitride layer, the buffer oxide layer, the conductive layer, the gate insulation layer, and the substrate 200 to form a trench (not shown). As a result, the patterned conductive layer 202 and the patterned gate insulation layer 201 are formed.

A first insulation layer for forming an isolation structure is filled in the trench. The first insulation layer may include a single layer structure or a stack structure. For instance, the first insulation layer may include a stack structure in consideration of an aspect ratio. When the first insulation layer includes a single layer structure, the first insulation layer may include a high density plasma (HDP) layer having a sufficient level of filling to result in a high aspect ratio. Also, the first insulation layer may include other oxide-based materials that have insulating properties. When the first insulation layer includes a stack structure, the first insulation layer may include a stack structure configured with a HDP layer, a spin on glass (SOG) layer, and another HDP layer. The SOG layer includes a polysilazane (PSZ) layer. The first insulation layer may include oxide-based materials that have insulating properties, such as borophosphosilicate glass (BPSG), phosphosilicate glass (PSG), undoped silicate glass (USG), tetraethyl orthosilicate (TEOS), or a combination thereof.

An etch process is performed to control an effective field oxide height (EFH) of the first insulation layer for forming the isolation structure formed in a cell region. The etch process is performed using a photoresist pattern which covers a peripheral region and exposes the cell region. The pad nitride layer is used as an etch barrier layer to selectively recess the first insulation layer in the trench. The peripheral region refers to a region where driving circuits for driving the cell, e.g., a decoder and a page buffer, will be formed. The etch process can use a buffered hydrogen fluoride (BHF) or buffered oxide etchant (BOE) solution having a high etch selectivity relative to nitride. Such solutions can include deionized water and hydrogen fluoride (HF) and are used to form the recessed first insulation layer 203. The photoresist pattern, the etched pad nitride layer, and the buffer oxide layer are removed.

Referring to FIG. 4B, a buffer layer 204 is formed over the surface profile of the resultant structure after the buffer oxide layer is removed. The buffer layer 204 functions as an etch barrier layer. The buffer layer 204 may include substantially the same material as the recessed first insulation layer 203.

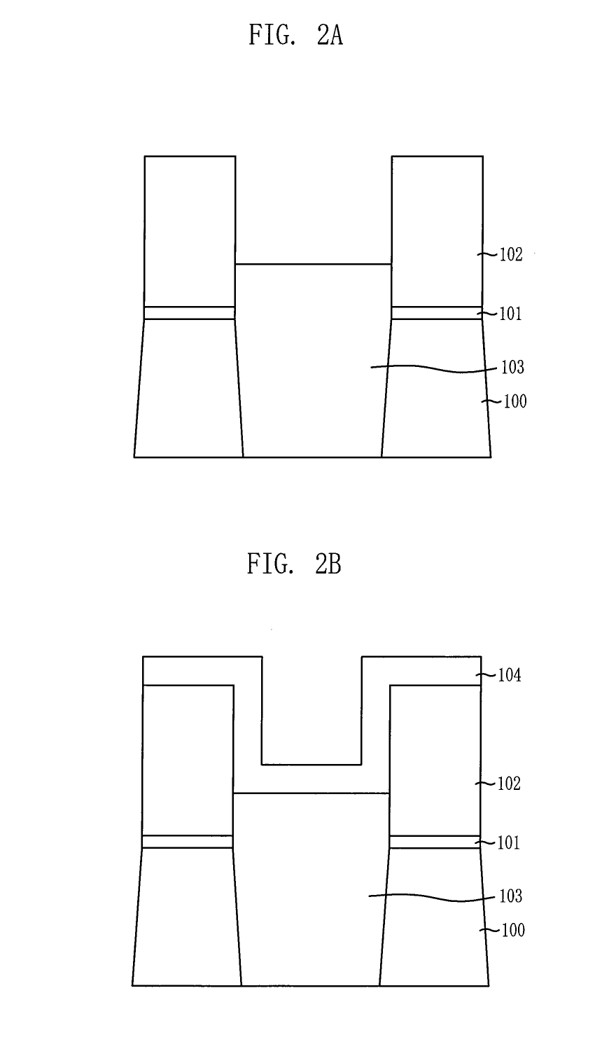

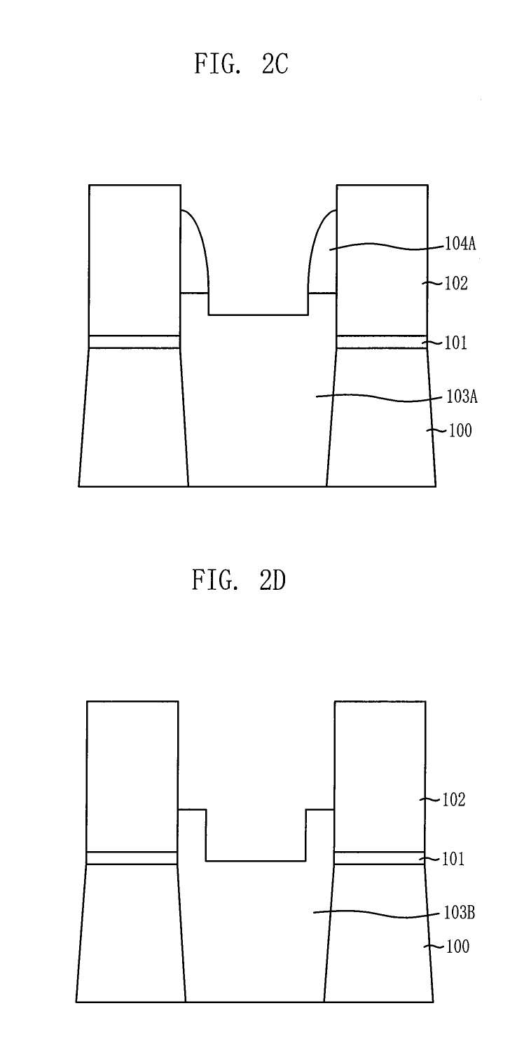

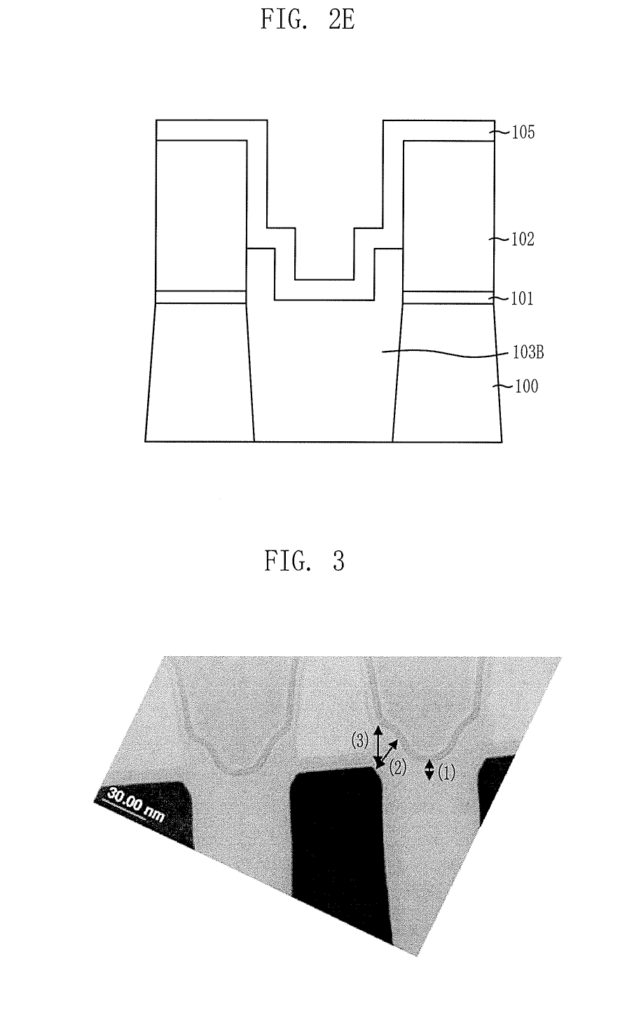

A second insulation layer 205 for forming wing spacers is formed over the buffer layer 204. The second insulation layer 205 includes a material having a high etch selectivity relative to the buffer layer 204. For instance, the second insulation layer 205 includes a nitride-based layer when the buffer layer 204 includes an oxide-based layer. Also, the second insulation layer 205 may include a polysilicon layer, an amorphous carbon layer, or a combination thereof. The total width of the buffer layer 204 and the second insulation layer 205 formed on inner sidewalls of the patterned conductive layer 202 is substantially the same as a width of a wing spacer oxide-based layer 104 formed on inner sidewalls of a polysilicon layer 102 according to a typical method shown in FIG. 2B.

Referring to FIG. 4C, an etch-back process is performed to selectively etch the second insulation layer 205 (FIG. 4B). The etch-back process uses a gas including fluoroform (CHF₃) and oxygen (O₂) or a CH₂F₂ gas to perform an anisotropic etch of the second insulation layer 205, which includes a nitride-based layer, e.g., silicon nitride (Si₃N₄), and the buffer layer 204, which includes an oxide-based layer, e.g., silicon oxide (SiO₂). As a result of the etch, wing spacers 205A are formed over regions corresponding to the inner sidewalls of the patterned conductive layer 202.

An etch process is performed to etch the buffer layer 204 using the wing spacers 205A as an etch barrier layer. Reference numeral 204A refers to an etched buffer layer 204A. The etch process is performed using a gas including CHF₃, octafluorocyclobutane (C₄F₈), and carbon monoxide (CO) when the buffer layer 204 includes an oxide-based layer, e.g., SiO₂, and the wing spacers 205A include a nitride-based layer. The recessed first insulation layer 203 including substantially the same material as the buffer layer 204 is aligned by the wing spacers 205A, and then a portion of the recessed first insulation layer 203 is etched. Thus, an etched first insulation layer 203A is formed. A depression aligned by the wing spacers 205A is generated over a middle portion of the etched first insulation layer 203A. The etch-back process, i.e., the wing spacer formation process, and the etch process, i.e., the buffer layer etch process, may be performed in substantially the same chamber in-situ using different etch gases.

Referring to FIG. 4D, the wing spacers 205A (FIG. 4C) are removed. The removal process is performed using a phosphoric acid (H₃PO₄) solution having a high etch selectivity to the etched buffer layer 204A.

Referring to FIG. 4E, the etched buffer layer 204A (FIG. 4D) is removed. The removal process is performed in consideration of the material comprising the patterned conductive layer 202. For instance, the removal process is performed using a BHF or BOE solution when the patterned conductive layer 202 includes polysilicon.

A width of the etched buffer layer 204A is smaller than wing spacers 104A according to the typical method shown in FIG. 2C. Thus, process time is decreased under substantially the same conditions as the typical method used in forming the wing spacers 104A. Furthermore, an exposure time of the etched first insulation layer 203A to the etch solution is less than the typical method. A shorter exposure time results in a decreased loss of the etched first insulation layer 203A. As a result, change in an EFH is minimized such that a uniform EFH may be obtained in the cell region. Reference numeral 203B refers to a further etched first insulation layer 203B. The removal processes for the wing spacers 205A and the etched buffer layer 204A are performed in substantially the same chamber in-situ using different etch solutions.

Referring to FIG. 4F, a dielectric layer 206 is formed over the surface profile of the resultant structure. The dielectric layer 206 may include a stack structure configured with an oxide-based layer, a nitride-based layer, and another oxide layer. The dielectric layer 206 may include a metal oxide-based layer with a dielectric constant of approximately 3.9 or greater. For instance, the dielectric layer 206 may include aluminum oxide (Al₂O₃), zirconium oxide (ZrO₂), hafnium oxide (HfO₂), or a combination thereof.

Although not shown, a control gate is formed over a dielectric layer 206. Subsequent processes are substantially the same as typical processes known in the art. Thus, descriptions for the subsequent processes are omitted herein.

In accordance with the embodiment of the present invention, the buffer layer is formed over the surface profile of the substrate on which the etch process for controlling the EFH is performed. The wing spacers are formed over the buffer layer using the material having a high etch selectivity relative to the buffer layer. Thus, the loss of the isolation structure is minimized when removing the wing spacers and the change in the EFH is minimized in the cell region. Therefore, a stable distribution of the cell programming threshold voltage by the EFH may be secured.

While the present invention has been described with respect to specific embodiments, the embodiments are illustrated for use as a description and not as a limitation. In particular, although the NAND type flash memory device is described as an example in the embodiments, the embodiments may be applied to other nonvolatile memory devices including a memory cell array configured with a string structure. Also, it will be apparent to those skilled in the art that various changes and modifications may be made without departing from the spirit and scope of the invention as defined in the following claims.

What is claimed is:

1. A method for fabricating a nonvolatile memory device, the method comprising:
forming a gate insulation layer and a gate conductive layer for forming a floating gate over a substrate;
etching a portion of the gate conductive layer, the gate insulation layer, and the substrate to form a trench;
forming an isolation structure by filling in the trench;
recessing the isolation structure to a certain depth in the trench;
forming a buffer layer over a resulting surface profile of the substrate structure;
forming spacers over sidewalls of the buffer layer corresponding to inner sidewalls of the trench, the spacers including a material having a high etch selectivity relative to the buffer layer;
etching a portion of the recessed isolation structure to form a depression in the isolation structure using the spacers;
removing the spacers;
removing the buffer layer;
forming a dielectric layer over the resulting surface profile of the substrate structure; and
forming a control gate over the dielectric layer.

2. The method of claim 1, wherein:
forming the buffer layer comprises forming an oxide-based layer, and
forming the spacers comprises forming a nitride-based layer.

3. The method of claim 1, wherein forming the isolation structure comprises forming the isolation structure using a material substantially the same as the buffer layer.

4. The method of claim 1, wherein forming the isolation structure comprises forming a single layer structure including a high density plasma (HDP) layer.

5. The method of claim 1, wherein forming the isolation structure comprises forming a stack structure including a HDP layer, a spin on glass (SOG) layer, and another HDP layer.

6. The method of claim 1, wherein forming the spacers comprises:
forming a spacer material for forming the spacers over the buffer layer; and
performing an etch-back process to etch the spacer material.

7. The method of claim 1, wherein etching the portion of the recessed isolation structure to form the depression comprises etching until portions of the buffer layer formed over the gate conductive layer are removed.

8. The method of claim 1, wherein forming the spacers and etching the portion of the recessed isolation structure to form the depression are performed in substantially the same chamber in-situ.

9. The method of claim 1, wherein removing the spacers and removing the buffer layer are performed in substantially the same chamber in-situ.

10. A method for fabricating a nonvolatile memory device including a cell region and a peripheral region, the method comprising:
forming a gate insulation layer and a gate conductive layer for forming a floating gate over a cell region and a peripheral region of a substrate;
etching a portion of the gate conductive layer, the gate insulation layer, and the substrate to form a trench;
forming an isolation structure by filling in the trench;
recessing a portion of the isolation structure formed in the cell region to a certain depth in the trench;
forming a buffer layer over a resulting surface profile of the substrate structure;
forming spacers over sidewalls of the buffer layer corresponding to inner sidewalls of the trench, the spacers including a material having a high etch selectivity relative to the buffer layer;
etching a portion of the recessed isolation structure to form a depression in the isolation structure using the spacers;
removing the spacers;
removing the buffer layer;
forming a dielectric layer over the resulting surface profile of the substrate structure; and
forming a control gate over the dielectric layer.

11. The method of claim 10, wherein:
forming the buffer layer comprises forming an oxide-based layer, and
forming the spacers comprises forming a nitride-based layer.

12. The method of claim 10, wherein forming the isolation structure comprises forming the isolation structure using a material substantially the same as the buffer layer.

13. The method of claim 10, wherein forming the isolation structure comprises forming a single layer structure including a high density plasma (HDP) layer.

14. The method of claim 10, wherein forming the isolation structure comprises forming a stack structure including a HDP layer, a spin on glass (SOG) layer, and another HDP layer.

15. The method of claim 10, wherein forming the spacers comprises:
forming a spacer material for forming the spacers over the buffer layer; and
performing an etch-back process to etch the spacer material.

16. The method of claim 10, wherein etching the portion of the recessed isolation structure to form the depression comprises etching until portions of the buffer layer formed over the gate conductive layer are removed.

17. The method of claim 10, wherein forming the spacers and etching the portion of the recessed isolation structure to form the depression are performed in substantially the same chamber in-situ.

18. The method of claim 10, wherein removing the spacers and removing the buffer layer are performed in substantially the same chamber in-situ.
